(19) United States
(12) Patent Application Publication
(10) Pub. No.: US 2017/0139628 A1
(43) Pub. Date: May 18, 2017

(54) ELECTRONIC DEVICE

(71) Applicant: SK hynix Inc., Icheon (KR)

(72) Inventors: Jung-Hyuk YOON, Icheon (KR); Ki-Myung KYUNG, Icheon (KR)

(21) Appl. No.: 15/157,160

(22) Filed: May 17, 2016

(30) Foreign Application Priority Data
Nov. 13, 2015 (KR) 10-2015-0159668

(51) Int. Cl. G06F 3/06; G11C 13/00

(52) U.S. Cl. CPC G06F 3/0626; G11C 13/004; G11C 13/0069; G11C 13/0038; G06F 3/0656; G06F 3/0659; G06F 3/0679

(57) ABSTRACT

An electronic device includes semiconductor memory. The semiconductor memory includes a cell array comprising a plurality of resistive memory cells arranged in a plurality of columns and a plurality of rows; and an access circuit applying a first voltage or a second voltage to a first node of a selected memory cell of the plurality of resistive memory cells, and applying a third voltage to a second node of the selected memory cell, the third voltage having a magnitude that is substantially the same as that of the first voltage and having a polarity that is opposite to a polarity of the first voltage.

### CROSS-REFERENCE TO RELATED APPLICATION(S)

The present application claims priority of Korean Patent Application No. 10-2015-0159668, filed on Nov. 13, 2015, which is incorporated herein by reference in its entirety.

### BACKGROUND

1. Field

Exemplary embodiments of the present disclosure relate to a memory circuit or device and some applications of the memory circuit or device in an electronic device.

2. Description of the Related Art

Recently, research has been actively carried out on memory devices for replacing DRAM and flash memory. One of such memory devices is a resistive memory device using a material that has a resistance value that varies depending on a bias applied thereto and switches between different resistance states. That is, the resistive memory device uses a variable resistance material. Representative examples of the resistive memory device may include a resistive random access memory (RRAM) device, a phase-change random access memory (PRAM) device, a magnetic random access memory (MRAM) device, and a ferroelectric random access memory (FRAM) device.

### SUMMARY

Various embodiments are directed to an electronic device in which a circuit for applying a specific voltage to both ends of a selected resistive memory cell occupies the area smaller than that of the prior art.

In an embodiment, an electronic device includes semiconductor memory. The semiconductor memory may include a cell array comprising a plurality of resistive memory cells arranged in a plurality of columns and a plurality of rows; and an access circuit applying a first voltage or a second voltage to a first end of a selected memory cell of the plurality of resistive memory cells, and applying a third voltage to a second end of the selected memory cell, the third voltage having a magnitude that is substantially the same as that of the first voltage and having a polarity that is opposite to a polarity of the first voltage.

Each of the plurality of resistive memory cells may have a high resistance state or a low resistance state depending on a value of data stored in said each of the plurality of resistive memory cells.

When a write operation is performed, a resistance value of the selected memory cell changes when a write voltage is applied to the first and second ends of the selected memory cell, and data is stored in the selected memory cell, and when a read operation is performed, a read current corresponding to a resistance value of the selected memory cell flows through the selected memory cell when a read voltage is applied to the first and second ends of the selected memory cell.

The first voltage may have a magnitude corresponding to half of the write voltage and has the same polarity as the write voltage.

The second voltage may have a magnitude corresponding to a value obtained by subtracting a voltage that is half of the write voltage from the read voltage, the second voltage having the same polarity as the read voltage.

The first voltage may have a magnitude corresponding to half of the read voltage and has the same polarity as the read voltage.

The second voltage may have a magnitude corresponding to a value obtained by subtracting a voltage that is half of the read voltage from the write voltage, the second voltage having the same polarity as the write voltage.

The write voltage may vary depending on a value of data to be written in the selected memory cell.

The access circuit may include first to third voltage pumps generating the first to third voltages, respectively; first to third driving units applying the first to third voltages to the first and second ends of the selected memory cell; and first to third capacitors, each of which is coupled between a corresponding one of the first to third voltage pumps and a corresponding one of the first to third driving units.

The electronic device further comprising a microprocessor which may include: a control unit that is configured to receive a signal including a command from an outside of the microprocessor, and performs extracting, decoding of the command, or controlling input or output of a signal of microprocessor; and an operation unit configured to perform an operation based on a result that the control unit decodes the command; and a memory unit configured to store data for performing the operation, data corresponding to a result of performing the operation, or an address of data for which the operation is performed, wherein the semiconductor memory unit that includes the variable resistance element is part of the memory unit in the microprocessor.

The electronic device further comprising a processor which may include: a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the semiconductor memory unit that includes the variable resistance element is part of the cache memory unit in the processor.

The electronic device further comprising a processing system which may include: a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between the processor, the auxiliary memory device or the main memory device and the outside, wherein the semiconductor memory unit that includes the variable resistance element is part of the auxiliary memory device or the main memory device in the processing system.

The electronic device further comprising a data storage system which may include: a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory unit that includes the variable resistance element is part of the storage device or the temporary storage device in the data storage system.

The electronic device may further include a memory system. The memory system include a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory unit that includes the variable resistance element is part of the memory or the buffer memory in the memory system.

In an embodiment, an electronic device includes semiconductor memory. The semiconductor memory may include a plurality of column lines; a plurality of row lines; a plurality of resistive memory cells arranged at intersections of the plurality of column lines and the plurality of row lines, each of the plurality of resistive memory cells being coupled between a corresponding one of the plurality of column lines and a corresponding one of the plurality of row lines; a column circuit applying a first voltage or a second voltage to a selected column line of the plurality of column lines; and a row circuit applying a third voltage to a selected row line of the plurality of row lines, wherein the third voltage has a magnitude that is substantially the same as that of the first voltage and has a polarity that is opposite to a polarity of the first voltage.

Each of the plurality of resistive memory cells may have a high resistance state or low resistance state depending on a value of data stored in said each of the plurality of resistive memory cells.

When a write operation may be performed, a resistance value of a selected resistive memory cell changes when a write voltage is applied to first and second ends of the selected resistive memory cell and data is stored in the selected resistive memory cell.

When a read operation may be performed, a read current corresponding to a resistance value of the selected resistive memory cell flows through the selected resistive memory cell when a read voltage is applied to the selected resistive memory cell, and wherein the selected resistive memory cell is coupled between the selected column line and the selected row line.

The first voltage may have a magnitude corresponding to half of the write voltage and has the same polarity as the write voltage.

The second voltage may have a magnitude corresponding to a value obtained by subtracting a voltage that is half of the write voltage from the read voltage, the second voltage having the same polarity as the read voltage.

The first voltage may have a magnitude corresponding to half of the read voltage and has the same polarity as the read voltage.

The second voltage may have a magnitude corresponding to a value obtained by subtracting a voltage that is half of the read voltage from the write voltage, the second voltage having the same polarity as the write voltage.

The write voltage may vary depending on a value of data to be written in the selected resistive memory cell.

The column circuit may include first and second voltage pumps generating the first and second voltages, respectively; first and second driving units applying the first and second voltages to the selected column line, respectively; and first and second capacitors, each of which is coupled between a corresponding one of the first and second voltage pumps and a corresponding one of the first and second driving units.

The row circuit may include a third voltage pump generating the third voltage; a third driving unit applying the third voltage to the selected row line; and a third capacitor coupled between the third voltage pump and the third driving unit.

The electronic device further comprising a microprocessor which may include: a control unit that is configured to receive a signal including a command from an outside of the microprocessor, and performs extracting, decoding of the command, or controlling input or output of a signal of microprocessor; and an operation unit configured to perform an operation based on a result that the control unit decodes the command; and a memory unit configured to store data for performing the operation, data corresponding to a result of performing the operation, or an address of data for which the operation is performed, wherein the semiconductor memory unit that includes the variable resistance element is part of the memory unit in the microprocessor.

The electronic device further comprising a processor which may include: a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the semiconductor memory unit that includes the variable resistance element is part of the cache memory unit in the processor.

The electronic device further comprising a processing system which may include: a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between the processor, the auxiliary memory device or the main memory device and the outside, wherein the semiconductor memory unit that includes the variable resistance element is part of the auxiliary memory device or the main memory device in the processing system.

The electronic device further comprising a data storage system which may include: a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory unit that includes the variable resistance element is part of the storage device or the temporary storage device in the data storage system.

The electronic device may further include a memory system. The memory system include a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory unit that includes the variable resistance element is part of the memory or the buffer memory in the memory system.

### BRIEF DESCRIPTION OF THE DRAWINGS

FIG. 1 illustrates a cell array of a resistive memory device.

FIGS. 2A and 2B respectively illustrate write and read operations that are performed on a memory cell in the cell array of FIG. 1.

FIG. 3 illustrates a semiconductor device in accordance with an embodiment of the present disclosure.

FIGS. 4A and 4B respectively illustrate write and read operations that are performed in a memory device, in accordance with a first embodiment.

FIGS. 5A and 5B respectively illustrate write and read operations that are performed in a memory device, in accordance with a second embodiment.

FIGS. 6A and 6B illustrate circuits and operations for applying voltages to a selected resistive memory cell in a memory device in accordance with the first embodiment.

FIGS. 7A and 7B illustrate circuits and operations for applying voltages to a selected resistive memory cell in a memory device in accordance with the second embodiment.

FIG. 8 shows an example of a configuration diagram of a microprocessor implementing memory circuitry based on the disclosed technology.

FIG. 9 shows an example of a configuration diagram of a processor implementing memory circuitry based on the disclosed technology.

FIG. 10 shows an example of a configuration diagram of a system implementing memory circuitry based on the disclosed technology.

FIG. 11 shows an example of a configuration diagram of a data storage system implementing memory circuitry based on the disclosed technology.

FIG. 12 shows an example of a configuration diagram of a memory system implementing memory circuitry based on the disclosed technology.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

A resistive memory device includes a memory cell array having a cross point array structure. The memory cell array includes a plurality of lower electrodes (e.g., a plurality of row lines) and a plurality of upper electrodes (e.g., a plurality of column lines), which are disposed to cross each other. The memory cell array further includes memory cells that are disposed at intersections of the plurality of lower electrodes and the plurality of upper electrodes. Each of the memory cells includes a variable resistance element and a selection element that are connected in series.

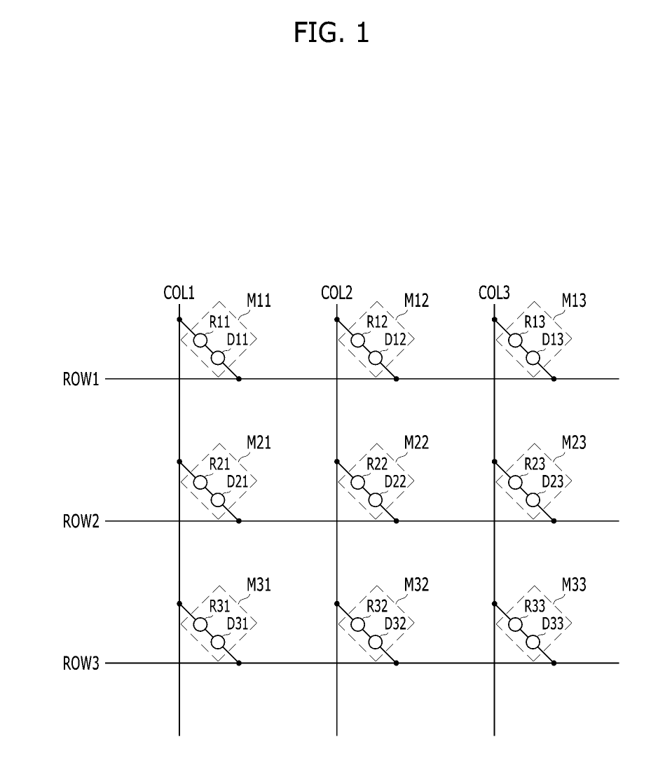

FIG. 1 illustrates a cell array of a resistive memory device.

Referring to FIG. 1, the cell array of the resistive memory device includes a plurality of row lines ROW1 to ROW3 (also called word lines), a plurality of column lines COL1 to COL3 (also called bit lines), and memory cells M11 to M33 respectively disposed at intersections of the plurality of row lines ROW1 to ROW3 and the column lines COL1 to COL3. Each of the memory cells M11 to M33 includes a corresponding one of selection elements D11 to D33 and a corresponding one of variable resistance elements R11 to R33 that are coupled in series. Each of the variable resistance elements R11 to R22 has a high resistance state or a low resistance state depending on a value of data stored in a corresponding memory cell. Diodes may be used as the selection elements D11 to D33.

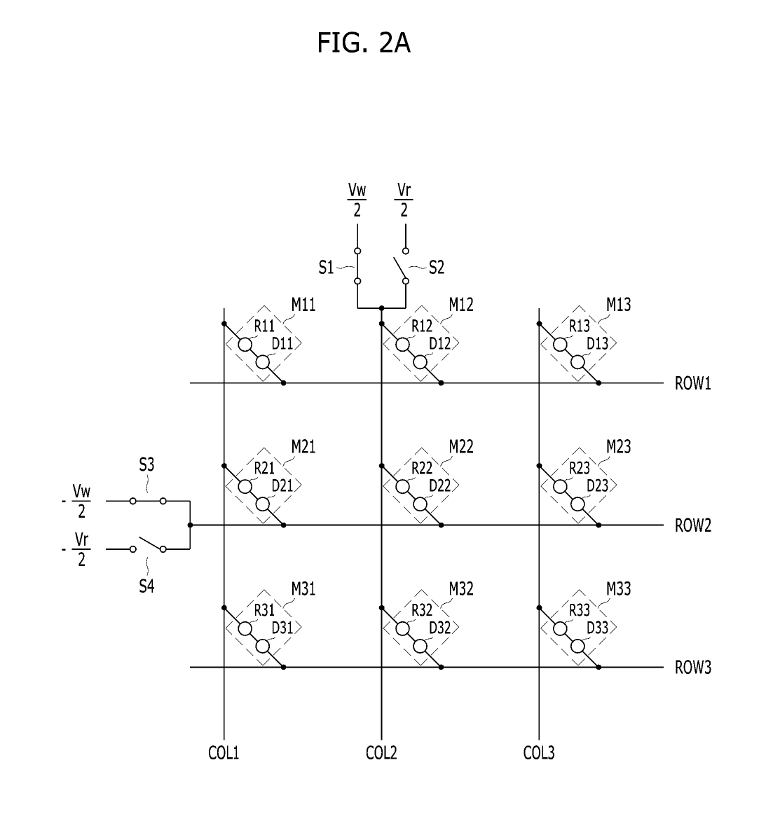

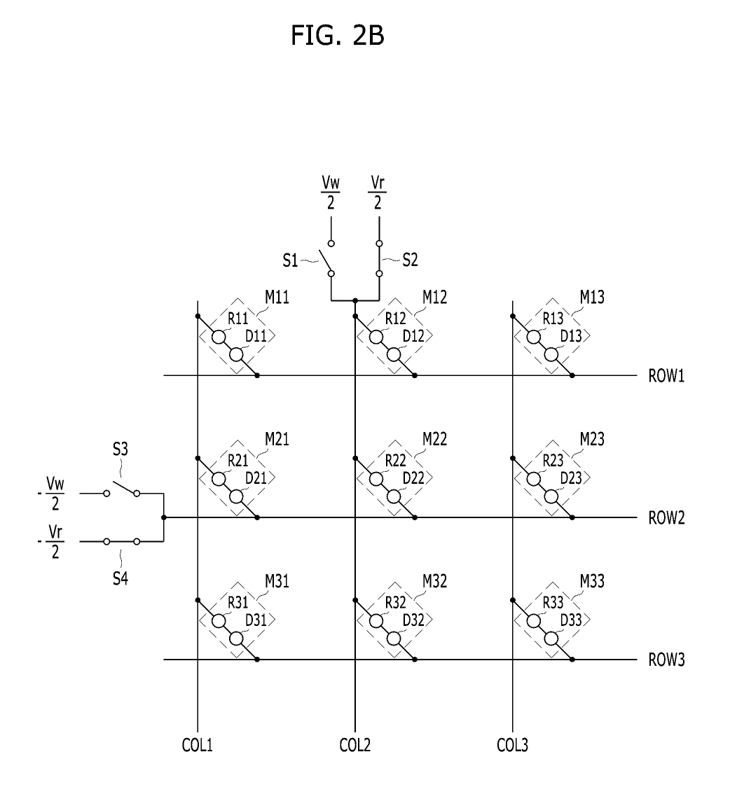

FIGS. 2A and 2B respectively illustrate levels of voltages applied to the cell array when write and read operations are performed on a selected memory cell, e.g., the memory cell M22, in FIG. 1.

Referring to FIG. 2A, when the write operation is performed on the selected memory cell M22, switches S1 and S3 are turned on. The switch S1 is connected to the column line COL 2 coupled to the selected memory cell M22, and the switch S3 is connected to the row line ROW2 coupled to the selected memory cell M22. Accordingly, a voltage Vw/2, which has a magnitude corresponding to half of a write voltage Vw and has the same polarity as the write voltage Vw, is applied to the selected column line COL2 coupled to the selected memory cell M22. A voltage −Vw/2, which has a magnitude corresponding to the half of the write voltage Vw and has a polarity opposite to the polarity of the write voltage Vw, is applied to the selected row line ROW2 coupled to the selected memory cell M22.

The write voltage Vw has a level sufficient to switch a resistance state of each of the variable resistance elements R11 to R33 of the resistive memory cells M11 to M33.

A ground voltage VSS or different voltages may be applied to the unselected column lines COL1 and COL3 and the unselected row lines ROW1 and ROW3, or the unselected column lines COL1 and COL3 and the unselected row lines ROW1 and ROW3 may be floated. In the drawings, voltages applied to the unselected column lines and the unselected row lines are not shown for illustrative convenience.

Referring to FIG. 2B, when the read operation is performed on the selected memory cell M22, switches S2 and S4 are turned on. The switch S2 is connected to the selected column line COL 2, and the switch S4 is connected to the selected row line ROW2. Accordingly, a voltage Vr/2, which has a magnitude corresponding to half of a read voltage Vr and has the same polarity as the read voltage Vr, is applied to the selected column line COL2 coupled to the selected memory cell M22. A voltage −Vr/2, which has a magnitude corresponding to the half of the read voltage Vr and has a polarity opposite to the polarity of the read voltage Vr, is applied to the selected row line ROW2 coupled to the selected memory cell M22. The read voltage Vr has a level sufficient for reading out data stored in each of the resistive memory cells M11 to M33.

A magnitude of a voltage applied to one of a selected column line and a selected row line can be reduced by applying the half voltage Vw/2, −Vw/2, Vr/2, or −Vr/2 to the other one of the selected column line or the selected row line in order to apply the write voltage Vw or the read voltage Vr to first and second nodes, e.g., both ends, of the selected memory cell M22, as described above.

In this case, however, the area occupied by a circuit for accessing a selected memory cell is increased because the circuit includes voltage pumps for generating the four voltages Vw/2, −Vw/2, Vr/2, and −Vr/2, switches for selectively applying the four voltages Vw/2, −Vw/2, Vr/2, and −Vr/2 to the selected column and row lines, and reservoir capacitors.

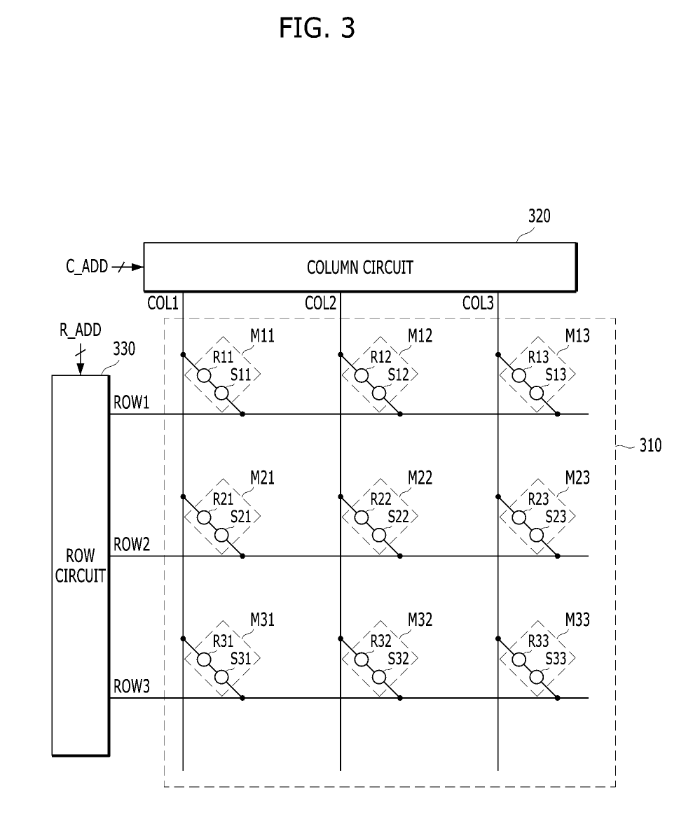

FIG. 3 illustrates a semiconductor device in accordance with an embodiment of the present disclosure.

Referring to FIG. 3, the semiconductor device may include a cell array 310, a column circuit 320, and a row circuit 330. The cell array 310 may include a plurality of column lines COL1 to COL3 (also called bit lines), a plurality of row lines ROW1 to ROW3 (also called word lines), and a plurality of memory cells M11 to M33 respectively disposed at intersections of the column lines COL1 to COL3 and the row lines ROW1 to ROW3. In FIG. 3, the cell array 310 includes 3 columns×3 rows, for convenience of description, but the cell array 310 may include several tens or hundreds of columns×several tens or hundreds of rows.

The column circuit 320 and the row circuit 330 apply a write voltage Vw or a read voltage Vr to both ends of a selected memory cell and sense a read current flowing into the selected memory cell. Thus, the column circuit 320 and the row circuit 330 may be collectively called an access circuit.

Each of the memory cells M11 to M33 may include a corresponding one of variable resistance elements R11 to R33 and a corresponding one of selection elements S11 to S33 coupled to the respective variable resistance elements R11 to R33 in series. Each of the variable resistance elements R11 to R33 may have a low resistance state (also called a set state) when first data (e.g., data ‘0’) is stored in a corresponding memory cell, or may have a high resistance state (also called a reset state) when second data (e.g., data ‘1’) is stored in the corresponding memory cell. The selection element may include an ovonic threshold switch (OTS) element.

In FIG. 3, the variable resistance elements R11 to R33 of the memory cells M11 to M33 are directly coupled to the column lines COL1 to COL3, and the selection elements S11 to S33 of the memory cells M11 to M33 are directly coupled to the row lines ROW1 to ROW3. However, configurations are not limited thereto. For example, the location of the variable resistance element and the location of the selection element may be reversed. That is, the variable resistance elements R11 to R33 may be directly coupled to the row lines ROW1 to ROW3, and the selection elements S11 to S33 may be directly coupled to the column lines COL1 to COL3.

A resistance state of each of the variable resistance elements R11 to R33 may switch when the write voltage Vw is applied to both ends of each of the resistive memory cells M11 to M33. In this case, the magnitude of the write voltage Vw may be changed depending on whether the resistance state of each of the variable resistance elements R11 to R33 switches to the low resistance state or the high resistance state. When the read voltage Vr is applied to both ends of each of the resistive memory cells M11 to M33, a read current corresponding to a resistance value of each of the variable resistance elements R11 to R33 may flow into each of the resistive memory cells M11 to M33. Accordingly, whether each of the variable resistance elements R11 to R33 has the low resistance state or the high resistance state, that is, whether data stored in each of the resistive memory cells M11 to M33 is the first data or the second data, may be determined by sensing such a read current.

The column circuit 320 may apply a first voltage V1 or a second voltage V2 to a selected column line of the column lines COL1 to COL3 that is selected by a column address C_ADD, and may apply a certain voltage to unselected column lines. The row circuit 330 may apply a third voltage V3 to a selected row line of the row lines ROW1 to ROW3 that is selected by a row address R_ADD, and may apply a certain voltage to unselected row lines. The third voltage V3 may have the same magnitude as the first voltage V1, but may have a polarity opposite to a polarity of the first voltage V1.

A magnitude and polarity of each of the first to third voltages V1 to V3 may be different in various embodiments. The magnitudes and polarities of the first to third voltages V1 to V3 are described below in connection with first and second embodiments.

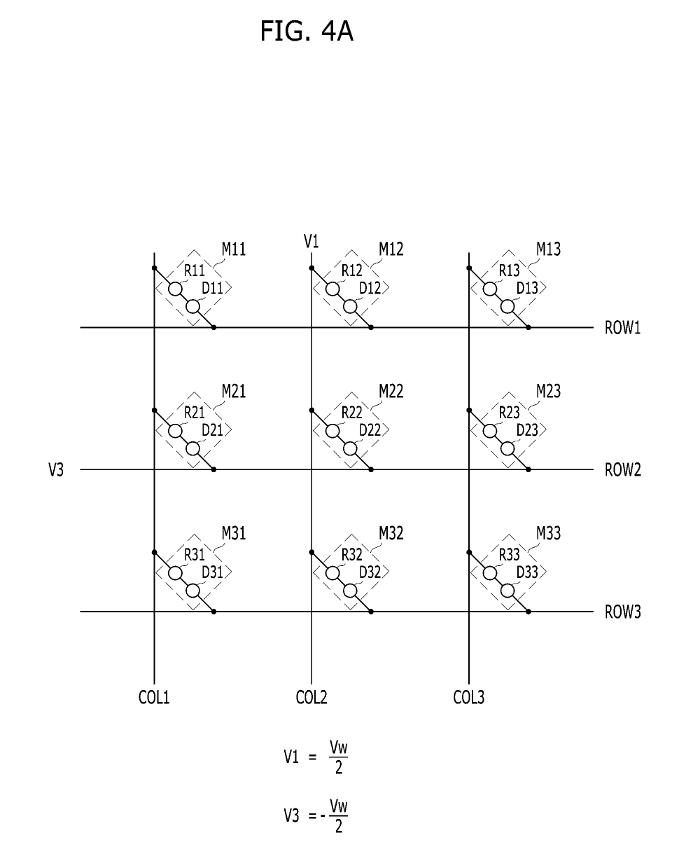

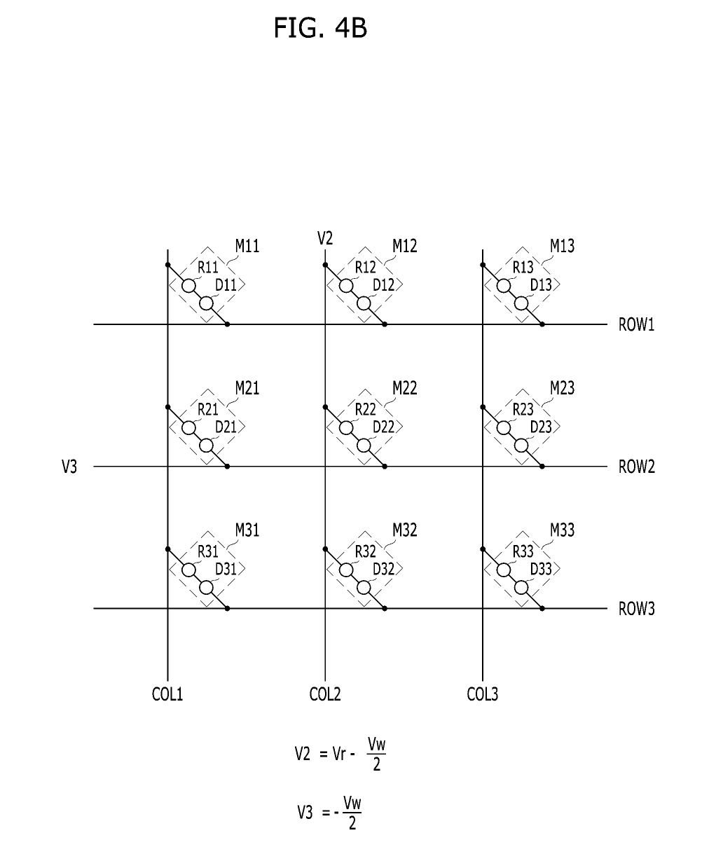

FIGS. 4A and 4B respectively illustrate voltages applied to both ends of the selected resistive memory cell M22 when write and read operations are performed in a memory device in accordance with a first embodiment.

In the first embodiment, the first voltage V1 may have a magnitude corresponding to half of the write voltage Vw, and may have the same polarity as the write voltage Vw. The second voltage V2 may have a value obtained by subtracting a voltage that is half of the write voltage Vw from the read voltage Vr, and may have the same polarity as the read voltage Vr. The third voltage V3 may have a magnitude corresponding to half of the write voltage Vw, and may have a polarity opposite to the polarity of the write voltage Vw. That is, the first to third voltages V1 to V3 may be represented as V1=Vw/2, V2=Vr−Vw/2, and V3=−Vw/2, respectively.

In the first embodiment, the column circuit 320 may apply the first voltage V1 to the selected column line COL2 when the write operation is performed, and may apply the second voltage V2 to the selected column line COL2 when the read operation is performed. The row circuit 330 may apply the third voltage V3 to the selected row line ROW2 when the write and read operations are performed. When the write operation is performed, the first voltage V1 (i.e., Vw/2) is applied to one end of the selected resistive memory cell M22, and the third voltage V3 (i.e., −Vw/2) is applied to the other end of the selected resistive memory cell M22. Accordingly, a voltage applied to the both ends of the selected resistive memory cell M22 may have substantially the same magnitude as the write voltage Vw when the write operation is performed. When the read operation is performed, the second voltage V2 (i.e., Vr−Vw/2) is applied to one end of the selected resistive memory cell M22 and the third voltage V3 (i.e., −Vw/2) is applied to the other end of the selected resistive memory cell M22. Accordingly, the voltage applied to both ends of the selected resistive memory cell M22 may have substantially the same magnitude as the read voltage Vr when the read operation is performed.

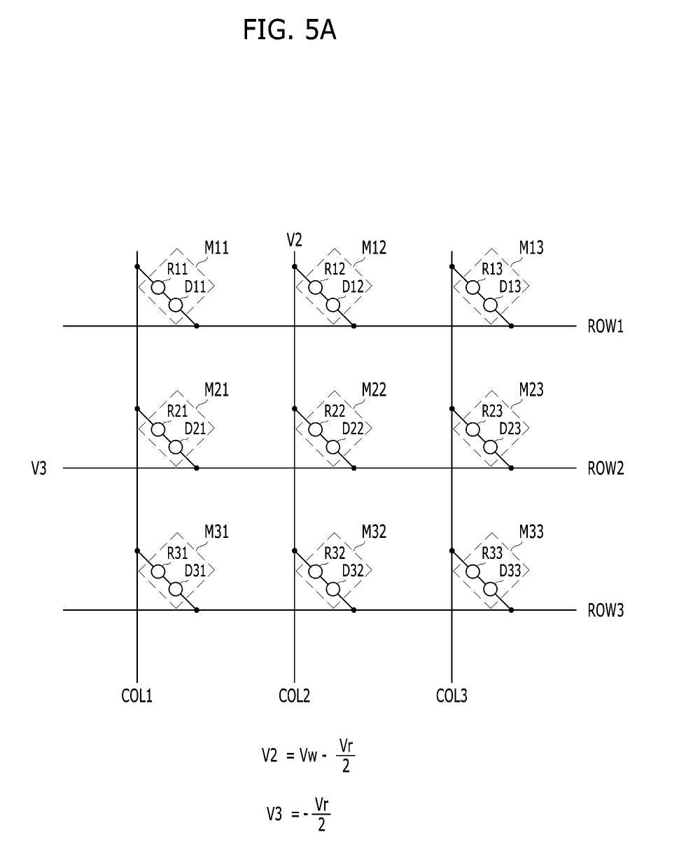

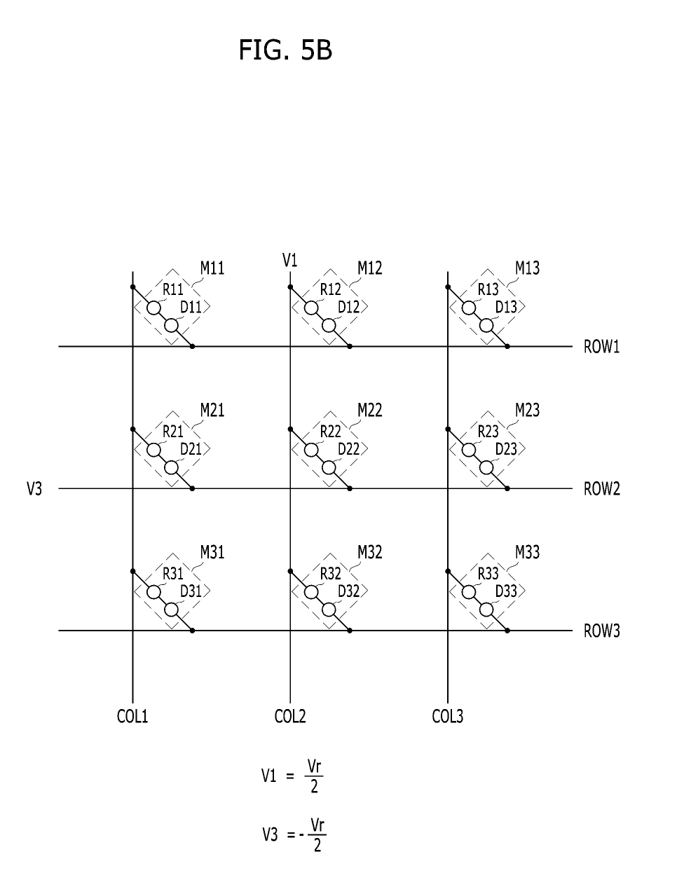

FIGS. 5A and 5B respectively illustrate voltages applied to both ends of the selected resistive memory cell M22 when write and read operations are performed in a memory device, in accordance with a second embodiment.

In the second embodiment, the first voltage V1 may have a magnitude corresponding to half of the read voltage Vr, and may have the same polarity as the read voltage Vr. The second voltage V2 may have a value obtained by subtracting a voltage that is half of the read voltage Vr from the write voltage Vw, and may have the same polarity as the write voltage Vw. The third voltage V3 may have a magnitude corresponding to the half of the read voltage Vr, and may have a polarity opposite to the polarity of the read voltage Vr. That is, the first to third voltages V1 to V3 may be represented as V1=Vr/2, V2=Vw−Vr/2, and V3=−Vr/2, respectively.

In the second embodiment, the column circuit 320 may apply the second voltage V2 to the selected column line COL2 when the write operation is performed, and may apply the first voltage V1 to the selected column line COL2 when the read operation is performed. The row circuit 330 may apply the third voltage V3 to the selected row line ROW2 when the write and read operations are performed. Accordingly, as in the first embodiment, the write voltage Vw may be applied to both ends of the selected resistive memory cell M22 when the write operation is performed, and the read voltage Vr may be applied to both ends of the selected resistive memory cell M22 when the read operation is performed.

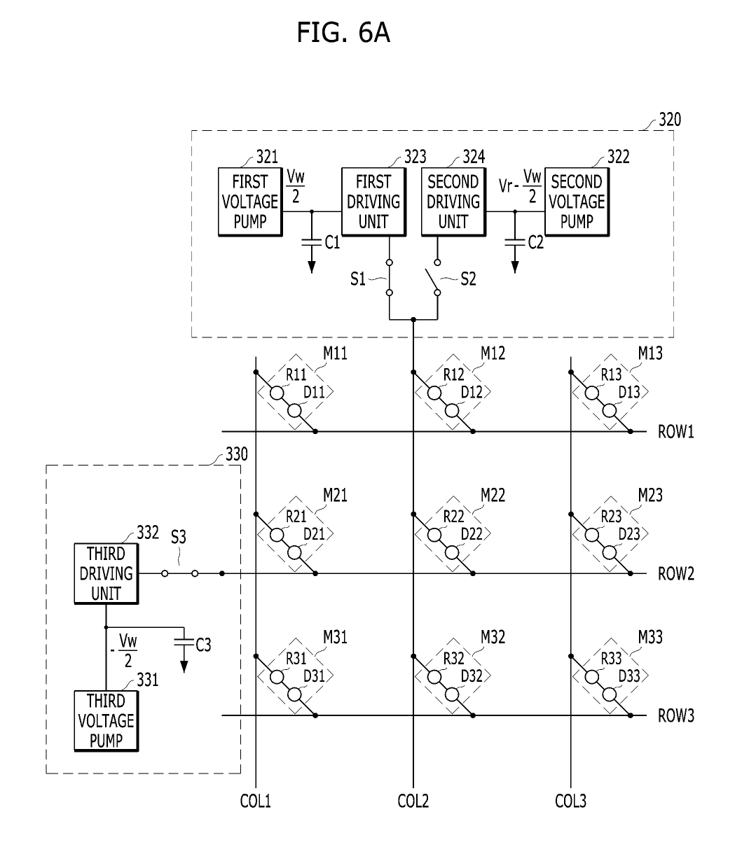

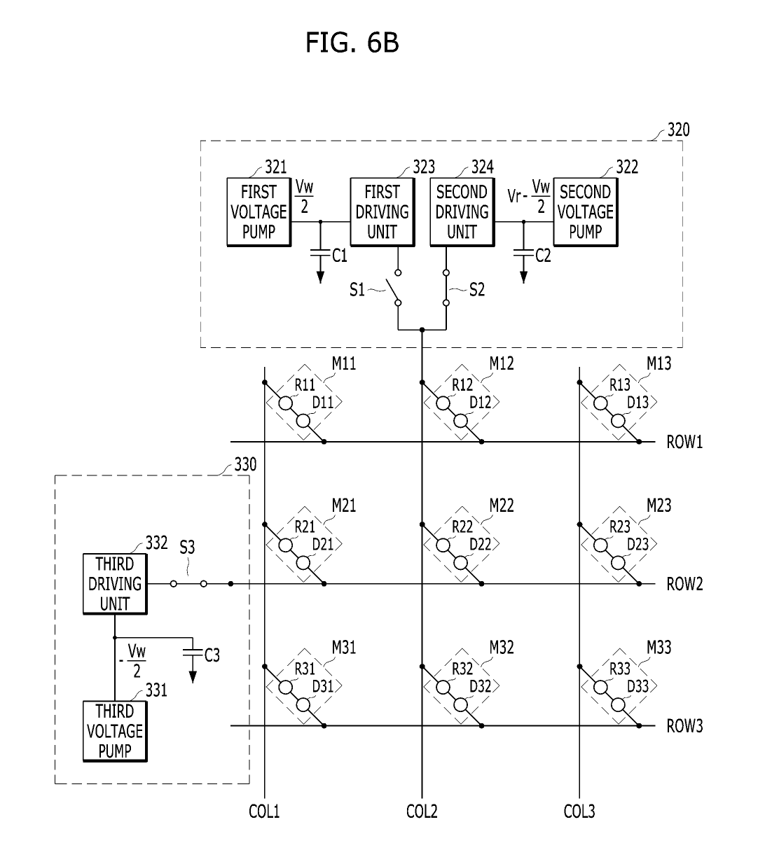

FIGS. 6A and 6B illustrate circuits and operations for applying voltages to the selected resistive memory cell M22 in the memory device in accordance with the first embodiment.

Referring to FIGS. 6A and 6B, the column circuit 320 may include first and second voltage pumps 321 and 322, first and second driving units 323 and 324, first and second capacitors C1 and C2, and first and second switches S1 and S2. The row circuit 330 may include a third voltage pump 331, a third driving unit 332, a third capacitor 333, and a third switch S3.

The first voltage pump 321 may generate the voltage Vw/2. The first driving unit 323 may include a write driver for driving a selected column line with the voltage Vw/2 generated by the first voltage pump 321 when the write operation is performed. The first capacitor C1 is disposed between the first voltage pump 321 and the first driving unit 323 and is coupled between a connection node of the first voltage pump 321 and the first driving unit 323 and a ground terminal. The first capacitor C1 may function as a reservoir capacitor for maintaining the stability of the first voltage V1, i.e., the voltage Vw/2. The first switch S1 is coupled between the first driving unit 323 and a column line, and may be turned on when the column line is selected by the column address C_ADD in the write operation.

The second voltage pump 322 may generate the voltage Vr−Vw/2. The second driving unit 324 may include a sense amplifier for driving the selected column line with the voltage Vr−Vw/2 generated by the second voltage pump 322 when the read operation is performed. The second capacitor C2 is disposed between the second voltage pump 322 and the second driving unit 324 and coupled between a connection node of the second voltage pump 322 and the second driving unit 324 and the ground terminal. The second capacitor C2 may function as a reservoir capacitor for maintaining the stability of the second voltage V2, i.e., the voltage Vr−Vw/2. The second switch S2 is coupled between the second driving unit 324 and a column line, and may be turned on when the column line is selected by the column address C_ADD when the read operation is performed.

The third voltage pump 331 may generate the voltage −Vw/2. The third driving unit 332 may include a driver for driving a selected column line with the voltage −Vw/2 generated by the third voltage pump 331 when the write and read operations are performed. The third capacitor C3 is disposed between the third voltage pump 331 and the third driving unit 332 and coupled between a connection node of the third voltage pump 331 and the third driving unit 332 and the ground terminal. The third capacitor C3 may function as a reservoir capacitor for maintaining the stability of the third voltage V3, i.e., the voltage −Vw/2. The third switch S3 is coupled between the third driving unit 332 and a row line, and may be turned on when the row line is selected by the row address R_ADD when the write and read operations are performed.

In the write operation, as shown in FIG. 6A, the first and third switches S1 and S3 may be turned on, and the second switch S2 may be turned off. On the other hand, in the read operation, as shown in FIG. 6B, the second and third switches S2 and S3 may be turned on, and the first switch S1 may be turned off.

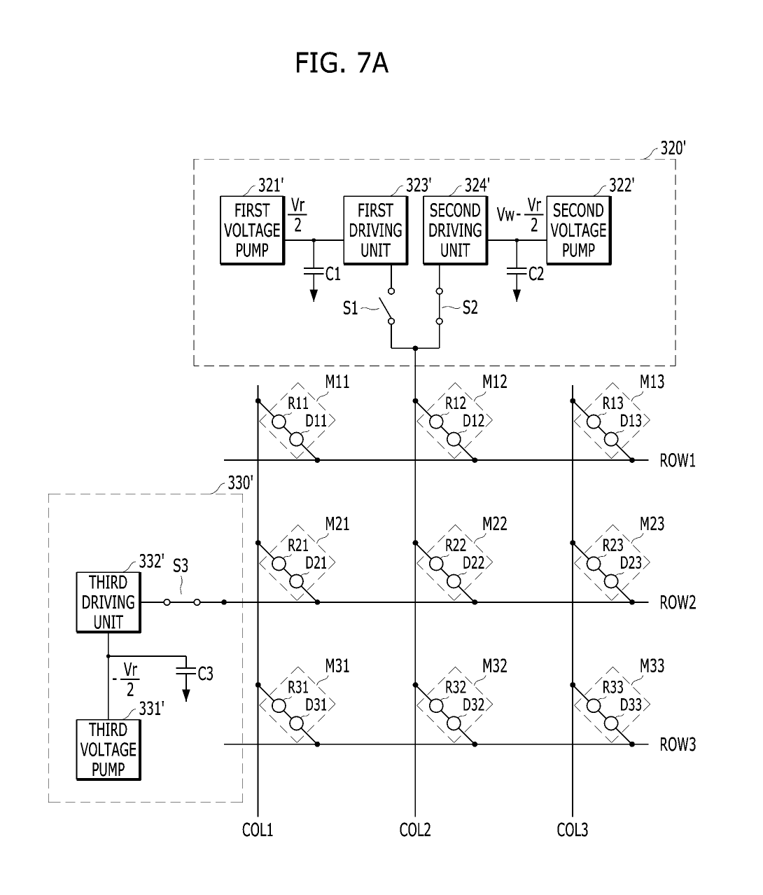

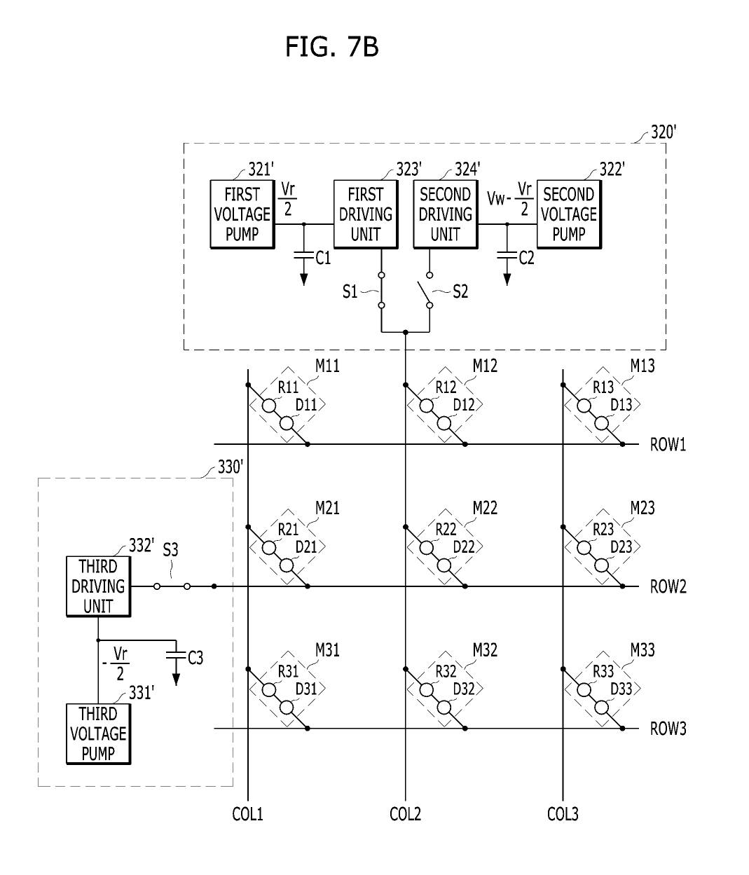

FIGS. 7A and 7B illustrate circuits and operations for applying voltages to the selected resistive memory cell M22 in a memory device in accordance with the second embodiment.

The circuits of FIGS. 7A and 7B are the same as those of FIGS. 6A and 6B except for levels of voltages generated by the voltage pumps and on/off states of the switches when write and read operations are performed.

Referring to FIGS. 7A and 7B, in a column circuit 320′, a first voltage pump 321′ generates the voltage Vr/2, a second voltage pump 322′ generates the voltage Vw−Vr/2, a first driving unit 323′ drives a selected column line with the voltage Vr/2 when the read operation is performed, and a second driving unit 324′ drives the selected column line with the voltage Vw−Vr/2 when the write operation is performed. In a row circuit 330′, a third voltage pump 331′ generates the voltage −Vr/2, and a third driving unit 332′ drives a selected row line with the voltage −Vr/2 when the read and write operations are performed.

In the write operation, as shown in FIG. 7A, the second and third switches S2 and S3 may be turned on, and the first switch S1 may be turned off. On the other hand, in the read operation, as shown in FIG. 7B, the first and third switches S1 and S3 may be turned on, and the second switch S2 may be turned off.

The memory device in accordance with the embodiments of the present disclosure can reduce four types of voltages, e.g., Vw/2, Vr/2, −Vw/2, and −Vr/2, which are used to apply write and read voltages, e.g., Vw and Vr, to both ends of a selected resistive memory cell to three types of voltages, e.g., V1, V2, and V3. Accordingly, the area occupied by a circuit for supplying the write and read voltages can be reduced because the number of pumps, capacitors, driving units, and switches used to supply the write and read voltages is reduced. Furthermore, a leakage current can be reduced when a base voltage is applied to an unselected column or row line. In FIGS. 6A and 6B and FIGS. 7A and 7B, both the pump(s) and the capacitor(s) have been illustrated as being included in the column or row circuit, but, in other embodiments, at least one of the pump(s) and the capacitor(s) may be present outside the column or row circuit.

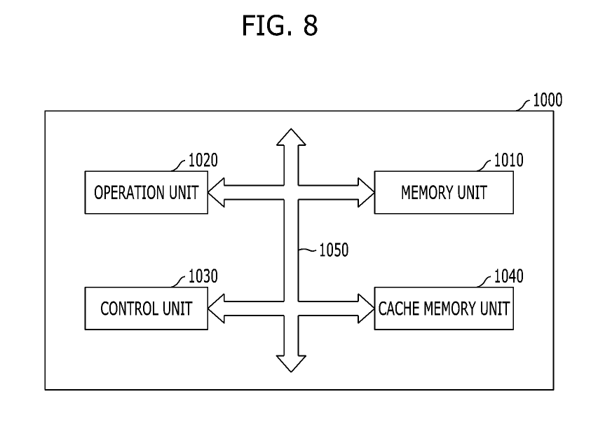

The above and other memory circuits or semiconductor devices based on the disclosed technology can be used in a range of devices or systems. FIGS. 8-12 provide some examples of devices or systems that can implement the memory circuits disclosed herein.

FIG. 8 shows an example of a configuration diagram of a microprocessor based on another implementation of the disclosed technology.

Referring to FIG. 8, a microprocessor 1000 may perform tasks for controlling and tuning a series of processes of receiving data from various external devices, processing the data, and outputting processing results to external devices. The microprocessor 1000 may include a memory unit 1010, an operation unit 1020, a control unit 1030, and so on. The microprocessor 1000 may be various data processing units such as a central processing unit (CPU), a graphic processing unit (GPU), a digital signal processor (DSP) and an application processor (AP).

The memory unit 1010 is a part which stores data in the microprocessor 1000, as a processor register, register or the like. The memory unit 1010 may include a data register, an address register, a floating point register and so on. Besides, the memory unit 1010 may include various registers. The memory unit 1010 may perform the function of temporarily storing data for which operations are to be performed by the operation unit 1020, result data of performing the operations and an address where data for performing of the operations are stored.

The memory unit 1010 may include one or more of the above-described semiconductor devices in accordance with the implementations. For example, the memory unit 1010 may include: a cell array capable of comprising a plurality of resistive memory cells arranged in a plurality of columns and a plurality of rows; and an access circuit capable of applying a first voltage or second voltage to a first end of a selected memory cell of the resistive memory cells and applying a third voltage which is identical with the first voltage and has a polarity opposite a polarity of the first voltage to a second end of the selected memory cell. Through this, a size of the memory unit 1010 may be reduced. Consequently, a size of the microprocessor 1000 may be improved.

The operation unit 1020 may perform four arithmetical operations or logical operations according to results that the control unit 1030 decodes commands. The operation unit 1020 may include at least one arithmetic logic unit (ALU) and so on.

The control unit 1030 may receive signals from the memory unit 1010, the operation unit 1020 and an external device of the microprocessor 1000, perform extraction, decoding of commands and controlling input and output of signals of the microprocessor, and execute processing represented by programs.

The microprocessor 1000 according to the present implementation may additionally include a cache memory unit 1040 which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

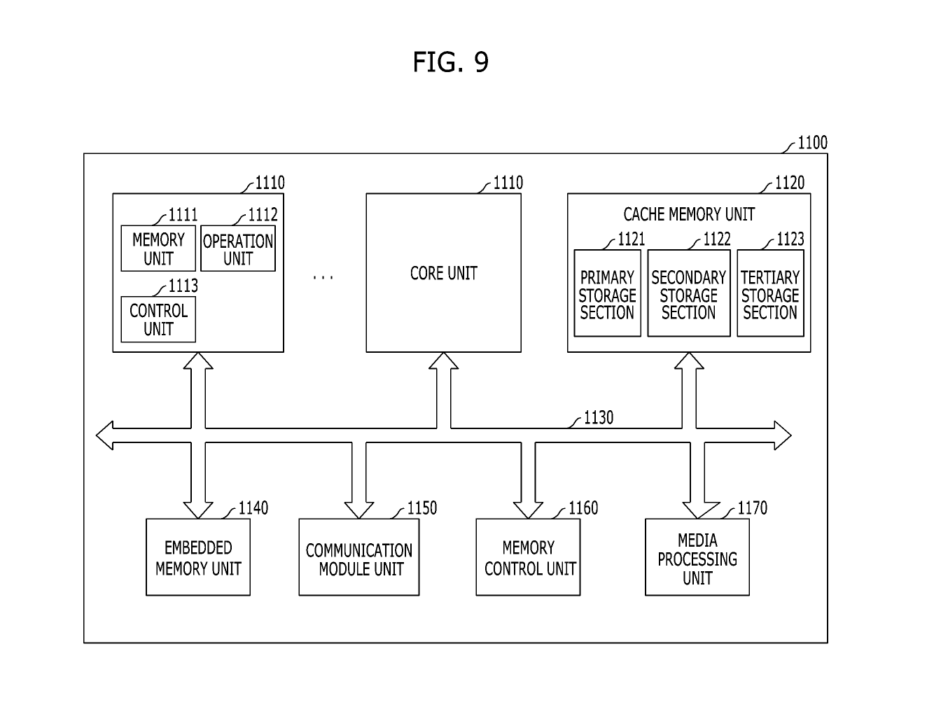

FIG. 9 is a configuration diagram of a processor based on another implementation of the disclosed technology.

Referring to FIG. 9, a processor 1100 may improve performance and realize multi-functionality by including various functions other than those of a microprocessor which performs tasks for controlling and tuning a series of processes of receiving data from various external devices, processing the data, and outputting processing results to external devices. The processor 1100 may include a core unit 1110 which serves as the microprocessor, a cache memory unit 1120 which serves to storing data temporarily, and a bus interface 1130 for transferring data between internal and external devices. The processor 1100 may include various system-on-chips (SoCs) such as a multi-core processor, a graphic processing unit (GPU) and an application processor (AP).

The core unit 1110 of the present implementation is a part which performs arithmetic logic operations for data inputted from an external device, and may include a memory unit 1111, an operation unit 1112 and a control unit 1113.

The memory unit 1111 is a part which stores data in the processor 1100, as a processor register, a register or the like. The memory unit 1111 may include a data register, an address register, a floating point register and so on. Besides, the memory unit 1111 may include various registers. The memory unit 1111 may perform the function of temporarily storing data for which operations are to be performed by the operation unit 1112, result data of performing the operations and an address where data for performing of the operations are stored. The operation unit 1112 is a part which performs operations in the processor 1100. The operation unit 1112 may perform four arithmetical operations, logical operations, according to results that the control unit 1113 decodes commands, or the like. The operation unit 1112 may include at least one arithmetic logic unit (ALU) and so on. The control unit 1113 may receive signals from the memory unit 1111, the operation unit 1112 and an external device of the processor 1100, perform extraction, decoding of commands, controlling input and output of signals of processor, and execute processing represented by programs.

The cache memory unit 1120 is a part which temporarily stores data to compensate for a difference in data processing speed between the core unit 1110 operating at a high speed and an external device operating at a low speed. The cache memory unit 1120 may include a primary storage unit 1121, a secondary storage unit 1122 and a tertiary storage unit 1123. In general, the cache memory unit 1120 includes the primary and secondary storage units 1121 and 1122, and may include the tertiary storage unit 1123 in the case where high storage capacity is required. As the occasion demands, the cache memory unit 1120 may include an increased number of storage units. That is to say, the number of storage units which are included in the cache memory unit 1120 may be changed according to a design. The speeds at which the primary, secondary and tertiary storage units 1121, 1122 and 1123 store and discriminate data may be the same or different. In the case where the speeds of the respective storage units 1121, 1122 and 1123 are different, the speed of the primary storage unit 1121 may be largest. At least one storage unit of the primary storage unit 1121, the secondary storage unit 1122 and the tertiary storage unit 1123 of the cache memory unit 1120 may include one or more of the above-described semiconductor devices in accordance with the implementations. For example, the cache memory unit 1120 may include: a plurality of resistive memory cells arranged in a plurality of columns and a plurality of rows; and an access circuit capable of applying a first voltage or second voltage to a first end of a selected memory cell of the resistive memory cells and applying a third voltage which is identical with the first voltage and has a polarity opposite a polarity of the first voltage to a second end of the selected memory cell. Through this, a size of the cache memory unit 1120 may be reduced. Consequently, a size of the processor 1100 may be reduced.

Although it was shown in FIG. 9 that all the primary, secondary and tertiary storage units 1121, 1122 and 1123 are configured inside the cache memory unit 1120, it is to be noted that all the primary, secondary and tertiary storage units 1121, 1122 and 1123 of the cache memory unit 1120 may be configured outside the core unit 1110 and may compensate for a difference in data processing speed between the core unit 1110 and the external device. Meanwhile, it is to be noted that the primary storage unit 1121 of the cache memory unit 1120 may be disposed inside the core unit 1110 and the secondary storage unit 1122 and the tertiary storage unit 1123 may be configured outside the core unit 1110 to strengthen the function of compensating for a difference in data processing speed. In another implementation, the primary and secondary storage units 1121, 1122 may be disposed inside the core units 1110 and tertiary storage units 1123 may be disposed outside core units 1110. The bus interface 1130 is a part which connects the core unit 1110, the cache memory unit 1120 and external device and allows data to be efficiently transmitted.

The processor 1100 according to the present implementation may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. In the case where the processor 1100 includes the plurality of core unit 1110, the primary storage unit 1121 of the cache memory unit 1120 may be configured in each core unit 1110 in correspondence to the number of the plurality of core units 1110, and the secondary storage unit 1122 and the tertiary storage unit 1123 may be configured outside the plurality of core units 1110 in such a way as to be shared through the bus interface 1130. The processing speed of the primary storage unit 1121 may be larger than the processing speeds of the secondary and tertiary storage unit 1122 and 1123. In another implementation, the primary storage unit 1121 and the secondary storage unit 1122 may be configured in each core unit 1110 in correspondence to the number of the plurality of core units 1110, and the tertiary storage unit 1123 may be configured outside the plurality of core units 1110 in such a way as to be shared through the bus interface 1130. The processor 1100 according to the present implementation may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data prepared in the processor 1100 or the data inputted from an external input device and outputs the processed data to an external interface device and so on. Besides, the processor 1100 may include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory) and a memory with similar functions to above mentioned memories, and so on. The nonvolatile memory may include a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), and a memory with similar functions.

The communication module unit 1150 may include a module capable of being connected with a wired network, a module capable of being connected with a wireless network and both of them. The wired network module may include a local area network (LAN), a universal serial bus (USB), an Ethernet, power line communication (PLC) such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

The memory control unit 1160 is to administrate and process data transmitted between the processor 1100 and an external storage device operating according to a different communication standard. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice and others from the external input device and output the data to the external interface device. The media processing unit 1170 may include a graphic processing unit (GPU), a digital signal processor (DSP), a high definition audio device (HD audio), a high definition multimedia interface (HDMI) controller, and so on.

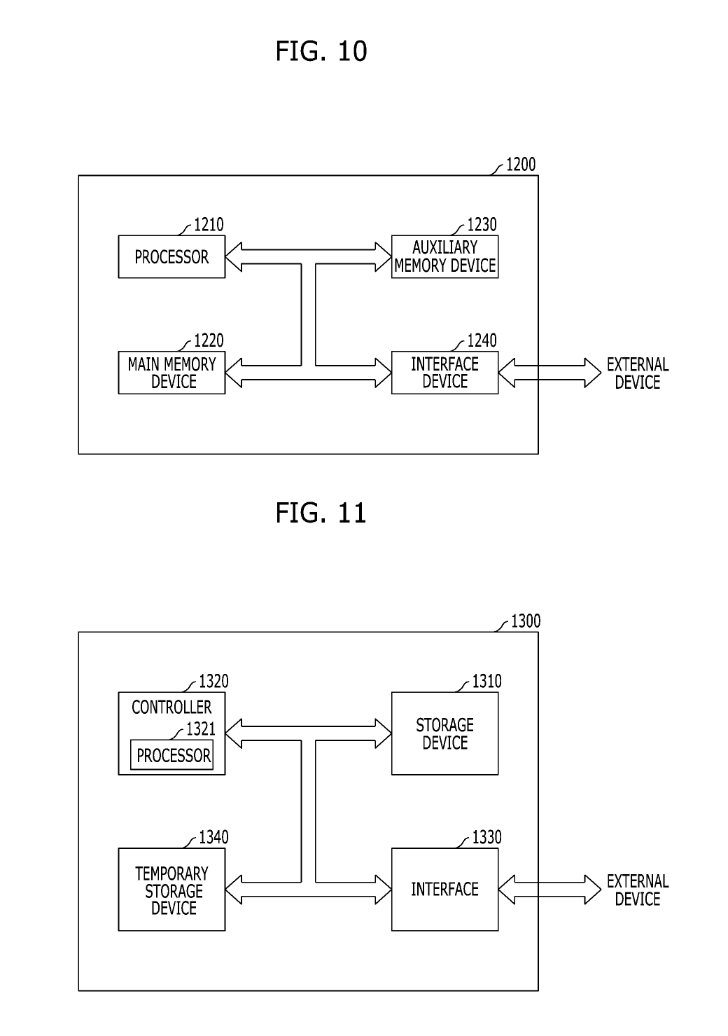

FIG. 10 is a configuration diagram of a system based on another implementation of the disclosed technology.

Referring to FIG. 10, a system 1200 as an apparatus for processing data may perform input, processing, output, communication, storage, etc. to conduct a series of manipulations for data. The system 1200 may include a processor 1210, a main memory device 1220, an auxiliary memory device 1230, an interface device 1240, and so on. The system 1200 of the present implementation may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 decodes inputted commands and processes operation, comparison, etc. for the data stored in the system 1200, and controls these operations. The processor 1210 may include a microprocessor unit (MPU), a central processing unit (CPU), a single/multi-core processor, a graphic processing unit (GPU), an application processor (AP), a digital signal processor (DSP), and so on.

The main memory device 1220 is a storage which can temporarily store, call and execute program codes or data from the auxiliary memory device 1230 when programs are executed and can conserve memorized contents even when power supply is cut off. The main memory device 1220 may include one or more of the above-described semiconductor devices in accordance with the implementations. For example, the main memory device 1220 may include: a plurality of resistive memory cells arranged in a plurality of columns and a plurality of rows; and an access circuit capable of applying a first voltage or second voltage to a first end of a selected memory cell of the resistive memory cells and applying a third voltage which is identical with the first voltage and has a polarity opposite a polarity of the first voltage to a second end of the selected memory cell. Through this, a size of the main memory device 1220 may be reduced. Consequently, a size of the system 1200 may be reduced.

Also, the main memory device 1220 may further include a static random access memory (SRAM), a dynamic random access memory (DRAM), and so on, of a volatile memory type in which all contents are erased when power supply is cut off. Unlike this, the main memory device 1220 may not include the semiconductor devices according to the implementations, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may include one or more of the above-described semiconductor devices in accordance with the implementations. For example, the auxiliary memory device 1230 may include: a plurality of resistive memory cells arranged in a plurality of columns and a plurality of rows; and an access circuit capable of applying a first voltage or second voltage to a first end of a selected memory cell of the resistive memory cells and applying a third voltage which is identical with the first voltage and has a polarity opposite a polarity of the first voltage to a second end of the selected memory cell. Through this, a size of the auxiliary memory device 1230 may be reduced. Consequently, a size of the system 1200 may be reduced.

Also, the auxiliary memory device 1230 may further include a data storage system (see the reference numeral 1300 of FIG. 11) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Unlike this, the auxiliary memory device 1230 may not include the semiconductor devices according to the implementations, but may include data storage systems (see the reference numeral 1300 of FIG. 11) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may be to perform exchange of commands and data between the system 1200 of the present implementation and an external device. The interface device 1240 may be a keypad, a keyboard, a mouse, a speaker, a mike, a display, various human interface devices (HIDs), a communication device and so on. The communication device may include a module capable of being connected with a wired network, a module capable of being connected with a wireless network and both of them.

The wired network module may include a local area network (LAN), a universal serial bus (USB), an Ethernet, power line communication (PLC), such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

FIG. 11 is a configuration diagram of a data storage system based on another implementation of the disclosed technology.

Referring to FIG. 11, a data storage system 1300 may include a storage device 1310 which has a nonvolatile characteristic as a component for storing data, a controller 1320 which controls the storage device 1310, an interface 1330 for connection with an external device, and a temporary storage device 1340 for storing data temporarily. The data storage system 1300 may be a disk type such as a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for, processing commands inputted through the interface 1330 from an outside of the data storage system 1300 and so on.

The interface 1330 is to perform exchange of commands and data between the data storage system 1300 and the external device. In the case where the data storage system 1300 is a card type, the interface 1330 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices.

In the case where the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on, or be compatible with the interfaces which are similar to the above mentioned interfaces. The interface 1330 may be compatible with one or more interfaces having a different type from each other. The temporary storage device 1340 can store data temporarily implementation for efficiently transferring data between the interface 1330 and the storage device 1310 according to diversifications and high performance of an interface with an external device, a controller and a system. For example, the temporary storage device 1340 may include: a plurality of resistive memory cells arranged in a plurality of columns and a plurality of rows; and an access circuit capable of applying a first voltage or second voltage to a first end of a selected memory cell of the resistive memory cells and applying a third voltage which is identical with the first voltage and has a polarity opposite a polarity of the first voltage to a second end of the selected memory cell. Through this, a size of the temporary storage device 1340 may be reduced. Consequently, a size of the data storage system 1300 may be reduced.

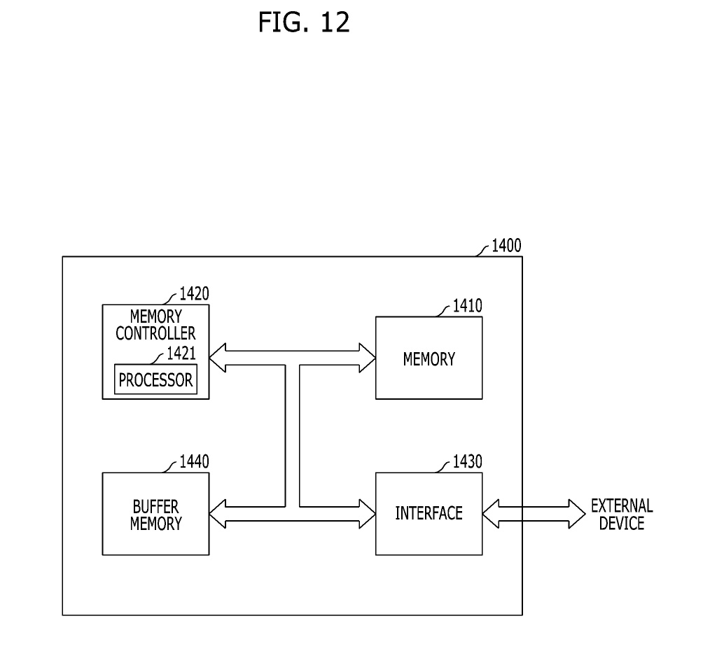

FIG. 12 is a configuration diagram of a memory system based on another implementation of the disclosed technology.

Referring to FIG. 12, a memory system 1400 may include a memory 1410 which has a nonvolatile characteristic as a component for storing data, a memory controller 1420 which controls the memory 1410, an interface 1430 for connection with an external device, and so on. The memory system 1400 may be a card type such as a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include: a plurality of resistive memory cells arranged in a plurality of columns and a plurality of rows; and an access circuit capable of applying a first voltage or second voltage to a first end of a selected memory cell of the resistive memory cells and applying a third voltage which is identical with the first voltage and has a polarity opposite a polarity of the first voltage to a second end of the selected memory cell. Through this, a size of the memory 1410 may be reduced. Consequently, a size of the memory system 1400 may be reduced.

Also, the memory 1410 according to the present implementation may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an outside of the memory system 1400.

The interface 1430 is to perform exchange of commands and data between the memory system 1400 and the external device. The interface 1430 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with one or more interfaces having a different type from each other.

The memory system 1400 according to the present implementation may further include a buffer memory 1440 for efficiently transferring data between the interface 1430 and the memory 1410 according to diversification and high performance of an interface with an external device, a memory controller and a memory system. For example, the buffer memory 1440 may include: a plurality of resistive memory cells arranged in a plurality of columns and a plurality of rows; and an access circuit capable of applying a first voltage or second voltage to a first end of a selected memory cell of the resistive memory cells and applying a third voltage which is identical with the first voltage and has a polarity opposite a polarity of the first voltage to a second end of the selected memory cell. Through this, a size of the buffer memory 1440 may be reduced. Consequently, a size of the memory system 1400 may be reduced.

Moreover, the buffer memory 1440 according to the present implementation may further include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic. Unlike this, the buffer memory 1440 may not include the semiconductor devices according to the implementations, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

Features in the above examples of electronic devices or systems in FIGS. 8-12 based on the memory devices disclosed in this document may be implemented in various devices, systems or applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described. Other implementations, enhancements and variations can be made based on what is described and illustrated in this patent document.

What is claimed is:

1. An electronic device comprising a semiconductor memory, wherein the semiconductor memory comprises:
a cell array comprising a plurality of resistive memory cells arranged in a plurality of columns and a plurality of rows; and
an access circuit applying a first voltage or a second voltage to a first node of a selected memory cell of the plurality of resistive memory cells, and applying a third voltage to a second node of the selected memory cell, the third voltage having a magnitude that is substantially the same as that of the first voltage and having a polarity that is opposite to a polarity of the first voltage.

2. The electronic device of claim 1, wherein each of the plurality of resistive memory cells has a high resistance state or a low resistance state depending on a value of data stored in said each of the plurality of resistive memory cells.

3. The electronic device of claim 1, wherein:
when a write operation is performed, a resistance value of the selected memory cell changes when a write voltage is applied to the first and second nodes of the selected memory cell, and data is stored in the selected memory cell, and
when a read operation is performed, a read current corresponding to a resistance value of the selected memory cell flows through the selected memory cell when a read voltage is applied to the first and second nodes of the selected memory cell,
wherein the first and second nodes are first and second ends of the selected memory cell.

4. The electronic device of claim 3, wherein:
the first voltage has a magnitude corresponding to half of the write voltage and has the same polarity as the write voltage, and
the second voltage has a magnitude corresponding to a value obtained by subtracting a voltage that is half of the write voltage from the read voltage, the second voltage having the same polarity as the read voltage.

5. The electronic device of claim 3, wherein:
the first voltage has a magnitude corresponding to half of the read voltage and has the same polarity as the read voltage, and
the second voltage has a magnitude corresponding to a value obtained by subtracting a voltage that is half of the read voltage from the write voltage, the second voltage having the same polarity as the write voltage.

6. The electronic device of claim 3, wherein the write voltage varies depending on a value of data to be written in the selected memory cell.

7. The electronic device of claim 1, wherein the access circuit comprises:
first to third voltage pumps generating the first to third voltages, respectively;
first to third driving units applying the first to third voltages to the first and second nodes of the selected memory cell; and
first to third capacitors, each of which is coupled between a corresponding one of the first to third voltage pumps and a corresponding one of the first to third driving units.

8. The electronic device according to claim 1, further comprising a microprocessor which includes:
a control unit that is configured to receive a signal including a command from an outside of the microprocessor, and performs extracting, decoding of the command, or controlling input or output of a signal of microprocessor; and
an operation unit configured to perform an operation based on a result that the control unit decodes the command; and
a memory unit configured to store data for performing the operation, data corresponding to a result of performing the operation, or an address of data for which the operation is performed,
wherein the semiconductor memory unit that includes the variable resistance element is part of the memory unit in the microprocessor.

9. The electronic device according to claim 1, further comprising a processor which includes:
a core unit configured to perform, based on a command inputted from an outside of the processor, an operation corresponding to the command, by using data;
a cache memory unit configured to store data for performing the operation, data corresponding to a result of performing the operation, or an address of data for which the operation is performed; and
a bus interface connected between the core unit and the cache memory unit, and configured to transmit data between the core unit and the cache memory unit,
wherein the semiconductor memory unit that includes the variable resistance element is part of the cache memory unit in the processor.

10. The electronic device according to claim 1, further comprising a processing system which includes:
a processor configured to decode a command received by the processor and control an operation for information based on a result of decoding the command;
an auxiliary memory device configured to store a program for decoding the command and the information;
a main memory device configured to call and store the program and the information from the auxiliary memory device such that the processor can perform the operation using the program and the information when executing the program; and
an interface device configured to perform communication between the processor, the auxiliary memory device or the main memory device and the outside,
wherein the semiconductor memory unit that includes the variable resistance element is part of the auxiliary memory device or the main memory device in the processing system.

11. The electronic device according to claim 1, further comprising a data storage system which includes:
a storage device configured to store data and conserve stored data regardless of power supply;
a controller configured to control input and output of data to and from the storage device according to a command inputted from an outside;
a temporary storage device configured to temporarily store data exchanged between the storage device and the outside; and
an interface configured to perform communication between at least one of the storage device, the controller and the temporary storage device and the outside,
wherein the semiconductor memory unit that includes the variable resistance element is part of the storage device or the temporary storage device in the data storage system.

12. The electronic device according to claim 1, further comprising a memory system which includes:
a memory configured to store data and conserve stored data regardless of power supply;
a memory controller configured to control input and output of data to and from the memory according to a command inputted from an outside;
a buffer memory configured to buffer data exchanged between the memory and the outside; and
an interface configured to perform communication between at least one of the memory, the memory controller and the buffer memory and the outside,
wherein the semiconductor memory unit that includes the variable resistance element is part of the memory or the buffer memory in the memory system.

13. An electronic device comprising a semiconductor memory, wherein the semiconductor memory comprises:
a plurality of column lines;
a plurality of row lines;
a plurality of resistive memory cells arranged at intersections of the plurality of column lines and the plurality of row lines, each of the plurality of resistive memory cells being coupled between a corresponding one of the plurality of column lines and a corresponding one of the plurality of row lines;
a column circuit applying a first voltage or a second voltage to a selected column line of the plurality of column lines; and
a row circuit applying a third voltage to a selected row line of the plurality of row lines, wherein the third voltage has a magnitude that is substantially the same as that of the first voltage and has a polarity that is opposite to a polarity of the first voltage.

14. The electronic device of claim 13, wherein each of the plurality of resistive memory cells has a high resistance state or low resistance state depending on a value of data stored in said each of the plurality of resistive memory cells.

15. The electronic device of claim 13, wherein:
when a write operation is performed, a resistance value of a selected resistive memory cell changes when a write voltage is applied to first and second nodes of the selected resistive memory cell and data is stored in the selected resistive memory cell, and
when a read operation is performed, a read current corresponding to a resistance value of the selected resistive memory cell flows through the selected resistive memory cell when a read voltage is applied to the selected resistive memory cell, and
wherein the selected resistive memory cell is coupled between the selected column line and the selected row line.

16. The electronic device of claim 15, wherein:
the first voltage has a magnitude corresponding to half of the write voltage and has the same polarity as the write voltage, and
the second voltage has a magnitude corresponding to a value obtained by subtracting a voltage that is half of the write voltage from the read voltage, the second voltage having the same polarity as the read voltage.

17. The electronic device of claim 15, wherein:
the first voltage has a magnitude corresponding to half of the read voltage and has the same polarity as the read voltage, and
the second voltage has a magnitude corresponding to a value obtained by subtracting a voltage that is half of the read voltage from the write voltage, the second voltage having the same polarity as the write voltage.

18. The electronic device of claim 15, wherein the write voltage varies depending on a value of data to be written in the selected resistive memory cell.

19. The electronic device of claim 13, wherein the column circuit comprises:
first and second voltage pumps generating the first and second voltages, respectively;
first and second driving units applying the first and second voltages to the selected column line, respectively; and
first and second capacitors, each of which is coupled between a corresponding one of the first and second voltage pumps and a corresponding one of the first and second driving units.

20. The electronic device of claim 13, wherein the row circuit comprises:
a third voltage pump generating the third voltage;
a third driving unit applying the third voltage to the selected row line; and
a third capacitor coupled between the third voltage pump and the third driving unit.

21. The electronic device according to claim 13, further comprising a microprocessor which includes:
a control unit that is configured to receive a signal including a command from an outside of the microprocessor, and performs extracting, decoding of the command, or controlling input or output of a signal of microprocessor; and
an operation unit configured to perform an operation based on a result that the control unit decodes the command; and
a memory unit configured to store data for performing the operation, data corresponding to a result of performing the operation, or an address of data for which the operation is performed,
wherein the semiconductor memory unit that includes the variable resistance element is part of the memory unit in the microprocessor.

22. The electronic device according to claim 13, further comprising a processor which includes:
a core unit configured to perform, based on a command inputted from an outside of the processor, an operation corresponding to the command, by using data;
a cache memory unit configured to store data for performing the operation, data corresponding to a result of performing the operation, or an address of data for which the operation is performed; and
a bus interface connected between the core unit and the cache memory unit, and configured to transmit data between the core unit and the cache memory unit,
wherein the semiconductor memory unit that includes the variable resistance element is part of the cache memory unit in the processor.

23. The electronic device according to claim 13, further comprising a processing system which includes:
a processor configured to decode a command received by the processor and control an operation for information based on a result of decoding the command;
an auxiliary memory device configured to store a program for decoding the command and the information;
a main memory device configured to call and store the program and the information from the auxiliary memory device such that the processor can perform the operation using the program and the information when executing the program; and
an interface device configured to perform communication between the processor, the auxiliary memory device or the main memory device and the outside,
wherein the semiconductor memory unit that includes the variable resistance element is part of the auxiliary memory device or the main memory device in the processing system.

24. The electronic device according to claim 13, further comprising a data storage system which includes:
a storage device configured to store data and conserve stored data regardless of power supply;
a controller configured to control input and output of data to and from the storage device according to a command inputted from an outside;
a temporary storage device configured to temporarily store data exchanged between the storage device and the outside; and
an interface configured to perform communication between at least one of the storage device, the controller and the temporary storage device and the outside,
wherein the semiconductor memory unit that includes the variable resistance element is part of the storage device or the temporary storage device in the data storage system.

25. The electronic device according to claim 13, further comprising a memory system which includes:
a memory configured to store data and conserve stored data regardless of power supply;
a memory controller configured to control input and output of data to and from the memory according to a command inputted from an outside;
a buffer memory configured to buffer data exchanged between the memory and the outside; and
an interface configured to perform communication between at least one of the memory, the memory controller and the buffer memory and the outside,
wherein the semiconductor memory unit that includes the variable resistance element is part of the memory or the buffer memory in the memory system.
